(19) United States
(12) Patent Application Publication
(10) Pub. No.: US 2026/0307913 A1
(43) Pub. Date: Oct. 8, 2026

(54) COLLECTION SUPPORT DEVICE AND COLLECTION SUPPORT METHOD

(71) Applicant: FUJI CORPORATION, Chiryu (JP)

(72) Inventors: Tomoya FUJIMOTO, Nagoya-shi (JP); Yuta YOKOI, Kariya-shi (JP); Takahiro KOBAYASHI, Chiryu-shi (JP)

(73) Assignee: FUJI CORPORATION, Chiryu (JP)

(21) Appl. No.: 19/483,333

(22) PCT Filed: Jun. 22, 2023
(86) PCT No.: PCT/JP2023/023162

§ 371 Date: Nov. 11, 2025

(51) Int. Cl. B65G 43/00; G06T 7/00

(52) U.S. Cl. CPC B65G 43/00; G06T 7/0008; G06T 7/001; B65G 2203/041; G06T 2207/30164

(57) ABSTRACT

A collection support device includes a track unit, a cavity unit, an imaging section, an update section, and a determination section. The imaging section captures a first cavity during an capturing available period in which it is expected that a component is not accommodated in the first cavity, for each of the first cavities which are at least one of multiple cavities and for which it is confirmed that the component has been collected by a component mounter. The update section updates a reference image obtained by capturing an empty cavity in which the component is not accommodated, using a first image obtained by capturing the first cavity by the imaging section, for each of the first cavities. The determination section determines whether the component is accommodated in the first cavity, using the reference image updated by the update section.

### TECHNICAL FIELD

The present description discloses a technique related to a collection support device and a collection support method.

### BACKGROUND ART

In a bulk component supply device described in Patent Literature 1, after leaded components are scattered onto a stage, each time an image of the stage is captured by a camera, post-scattering image data is compared with pre-scattering image data stored in a storage device. It is decided that a leaded component is present in a block in which the difference in brightness between the pre-scattering image data and the post-scattering image data is equal to or greater than a first threshold. That is, in a block in which the difference in brightness between the image data (pre-scattering image data) in which it is clear that a leaded component is not present and the image data (post-scattering image data) in which the presence of the lead component is unknown is equal to or greater than the first threshold, it is assumed that an object causing the difference in brightness is present, and thus it is decided that a leaded component is present in the block.

### CITATION LIST

### Patent Literature

Patent Literature 1: WO 2017/208325

### BRIEF SUMMARY

### Technical Problem

However, for example, a foreign object may adhere to a cavity in which a component is accommodated. For example, a foreign object such as a peeled-off electrode portion of the component has the same luminance as that of an electrode portion of the component, and a component mounter may erroneously detect the component from the foreign object. As a result, the component mounter may erroneously determine that a component is accommodated in the cavity even though the component is not accommodated in the cavity, and may fail to collect the component. In addition, even in a cavity regarded uncollectable due to adhesion of a foreign object, it may be possible to collect the component from the cavity regarded uncollectable, depending on a positional relationship between the component and the foreign object, for example, in a case where the foreign object is covered by a component.

In view of such circumstances, the present description discloses a collection support device and a collection support method capable of determining the presence or absence of a component in a cavity even in a case where a state of the cavity

### Solution to Problem

The present description discloses a collection support device including a track unit, a cavity unit, an imaging section, an update section, and a determination section. The track unit includes a conveyance path configured to convey a component discharged from a component case accommodating the component in a bulk state to a supply region in which the component is collectable by a component mounter. The cavity unit includes multiple cavities in the supply region, each of the cavities being configured to accommodate one of the components conveyed from the conveyance path to the supply region in the track unit. The imaging section captures an image of a first cavity during a capturing available period in which it is expected that the component is not accommodated in the first cavity, for each of the first cavities which are at least one of the multiple cavities and for which it is confirmed that the component has been collected by the component mounter. The update section updates a reference image obtained by capturing an empty cavity in which the component is not accommodated, using a first image obtained by capturing the first cavity by the imaging section, for each of the first cavities. The determination section determines whether the component is accommodated in the first cavity, using the reference image updated by the update section.

In addition, the present description discloses a collection support device including a track unit, a cavity unit, a storage section, and a decision section. The track unit includes a conveyance path configured to convey a component discharged from a component case accommodating the component in a bulk state to a supply region in which the component is collectable by a component mounter. The cavity unit includes multiple cavities in the supply region, each of the cavities being configured to accommodate one of the components conveyed from the conveyance path to the supply region in the track unit. The storage section stores a position of a second cavity in the cavity unit and an image feature value enabling identification of an erroneous detection portion that is erroneously detected as the component in a second image obtained by capturing the second cavity in association with each other in a storage device, for each of the second cavities which are at least one of the multiple cavities and for which it is confirmed that the component is not collectable by the component mounter. The decision section decides whether the component is accommodated in the second cavity, based on a degree of matching between the image feature value enabling identification of an inspection target portion detected as the component in an inspection image obtained by capturing the second cavity after accommodation of the component in the second cavity is attempted for supplying the component and the image feature value enabling identification of the erroneous detection portion stored in the storage device, for each of the second cavities.

Furthermore, the present description discloses a collection support method applied to a component collection of a bulk feeder including a track unit and a cavity unit, the collection support method including: an image capturing step, an updating step, and a determination step. The track unit includes a conveyance path configured to convey a component discharged from a component case accommodating the component in a bulk state to a supply region in which the component is collectable by a component cavities being configured to accommodate one of the components conveyed from the conveyance path to the supply region in the track unit. In the image capturing step, an image of a first cavity is captured during a capturing available period in which it is expected that the component is not accommodated in the first cavity, for each of the first cavities which are at least one of the multiple cavities and for which it is confirmed that the component has been collected by the component mounter. In the updating step, a reference image obtained by capturing an empty cavity in which the component is not accommodated is updated, using a first image obtained by capturing the first cavity in the image capturing step, for each of the first cavities. In the determination step, whether the component is accommodated in the first cavity is determined, using the reference image updated in the updating step.

In addition, the present description discloses a collection support method applied to a component collection of a bulk feeder including a track unit and a cavity unit, the collection support method including: a storage step and a decision step. The track unit includes a conveyance path configured to convey a component discharged from a component case accommodating the component in a bulk state to a supply region in which the component is collectable by a component mounter. The cavity unit includes multiple cavities in the supply region, each of the cavities being configured to accommodate one of the components conveyed from the conveyance path to the supply region in the track unit. In the storage step, a position of a second cavity in the cavity unit and an image feature value enabling identification of an erroneous detection portion that is erroneously detected as the component in a second image obtained by capturing the second cavity are stored in a storage device in association with each other, for each of the second cavities which are at least one of the multiple cavities and for which it is confirmed that the component is not collectable by the component mounter. In the decision step, whether the component is accommodated in the second cavity is decided, based on a degree of matching between the image feature value enabling identification of an inspection target portion detected as the component in an inspection image obtained by capturing the second cavity after accommodation of the component in the second cavity is attempted for supplying the component and the image feature value enabling identification of the erroneous detection portion stored in the storage device, for each of the second cavities.

### Advantageous Effects

According to the collection support device described above, it is possible to determine the presence or absence of the component in the cavity even in a case where the state of the cavity changes with the production of the product board. The above description for the collection support device can be similarly applied to the collection support method.

### BRIEF DESCRIPTION OF DRAWINGS

FIG. 1 is a plan view illustrating a configuration example of a component

FIG. 2 is a side view of the vicinity of a supply region illustrating an example of a bulk feeder.

FIG. 3 is a plan view as viewed in the direction of arrow III in FIG. 2.

FIG. 4 is a schematic diagram illustrating an example of a cavity to which a foreign object adheres.

FIG. 5 is a schematic diagram illustrating a recognition example in a case where the foreign object in FIG. 4 is erroneously detected as a component.

FIG. 6 is a block diagram illustrating an example of a control block of a collection support device.

FIG. 7 is a flowchart illustrating an example of a control procedure by the collection support device.

FIG. 8 is a schematic diagram illustrating a calculation example of a difference image. FIG. 9 is a schematic diagram illustrating another calculation example of the difference image.

FIG. 10 is a block diagram illustrating another example of the control block of the collection support device.

FIG. 11 is a flowchart illustrating another example of the control procedure of the collection support device.

FIG. 12 is a schematic diagram illustrating an example of an inspection image and a second image in a case where a component is accommodated in a second cavity.

FIG. 13 is a schematic diagram illustrating an example of an inspection image and a second image in a case where the component is not accommodated in the second cavity.

FIG. 14 is a schematic diagram illustrating an example of an inspection image and a second image in a case where a foreign object newly adheres to the second cavity.

### DESCRIPTION OF EMBODIMENTS

### 1. Embodiments

### 1-1. Configuration Example of Component Mounter 10

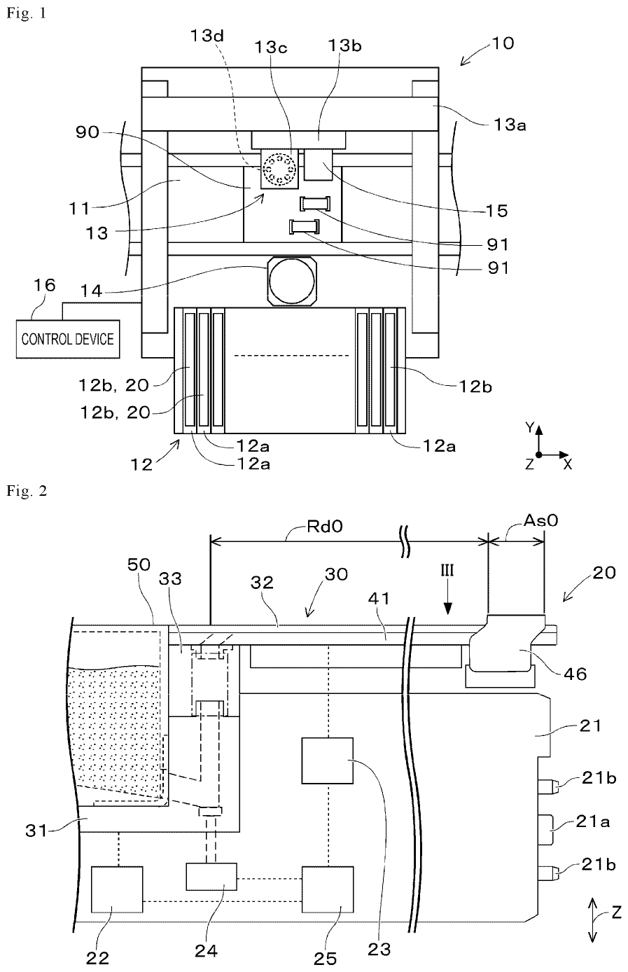

Component mounter 10 mounts component 91 on board 90. As illustrated in FIG. 1, component mounter 10 includes board conveyance device 11, component supply device 12, component transfer device 13, part camera 14, board camera 15, and control device 16. Collection support device 60 is applied to a component collection from bulk feeder 20 provided in component supply device 12.

For example, board conveyance device 11 includes a belt conveyor and the like, and conveys board 90 in a conveyance direction (X-axis direction). Board 90 is a circuit board on which an electronic circuit, an electric circuit, a magnetic circuit, and the like are formed. Board conveyance device 11 carries board 90 into component mounter 10 and positions board 90 at a predetermined position in component mounter 10. Board conveyance device 11 carries board 90 out of component mounter 10 after a mounting process of component 91 by component mounter 10 ends.

Component supply device 12 supplies component 91 to be mounted on board 90. Component supply device 12 includes multiple feeders 12b provided along the detachably attached to slot 12a. As feeder 12b of the embodiment, among a tape feeder and bulk feeder 20, at least bulk feeder 20 is used. The tape feeder pitch-feeds a carrier tape in which multiple components 91 are accommodated, and supplies component 91 at a supply position so that component 91 can be collected. Bulk feeder 20 supplies component 91 discharged from component case 50 accommodating component 91 in a bulk state (a state in which the postures of multiple components 91 are irregular) so that component mounter 10 can collect component 91.

Component transfer device 13 includes head drive device 13a, moving table 13b, mounting head 13c, and holding member 13d. Head drive device 13a is configured to move moving table 13b in the X-axis direction and a Y-axis direction (a direction orthogonal to the X-axis direction on a horizontal plane) by a linear motion mechanism. Mounting head 13c is provided on moving table 13b detachably (exchangeably) by a clamp member. Mounting head 13c collects and holds component 91 supplied by component supply device 12 with at least one holding member 13d, and mounts component 91 on board 90 positioned by board conveyance device 11. As holding member 13d, for example, a suction nozzle, a chuck, and the like can be used.

A well-known imaging device can be used as part camera 14 and board camera 15. Part camera 14 is fixed to a base of component mounter 10 such that an optical axis faces upward in a vertical direction (a Z-axis direction orthogonal to the X-axis direction and the Y-axis direction). Part camera 14 can capture an image of component 91 held by holding member 13d or the like from below. Board camera 15 is provided on moving table 13b of component transfer device 13 such that an optical axis faces downward in the vertical direction (Z-axis direction). Board camera 15 can capture an image of board 90 or the like from above. Part camera 14 and board camera 15 capture images based on a control signal transmitted from control device 16. Image data of the images captured by part camera 14 and board camera 15 is transmitted to control device 16.

Control device 16 includes a well-known computing device and a storage device, and is configured with a control circuit. Information, image data, and the like output from various sensors provided in component mounter 10 are input to control device 16. Control device 16 transmits the control signal to each device based on a control program, a predetermined mounting condition set in advance, and the like.

For example, control device 16 causes board camera 15 to capture an image of board 90 positioned by board conveyance device 11. Control device 16 performs image processing on the image captured by board camera 15 to recognize a positioning state of board 90. In addition, control device 16 causes holding member 13d to collect and hold component 91 supplied by component supply device 12, and causes part camera 14 to capture an image of component 91 held by holding member 13d. Control device 16 performs the image processing on the image captured by part camera 14 to recognize a holding posture of component 91.

Control device 16 moves holding member 13d above a planned mounting position set in advance by the control program or the like. In addition, control device 16 component 91 is actually mounted, based on the positioning state of board 90, the holding posture of component 91, and the like. The planned mounting position and the mounting position include a rotation angle in addition to the position (X-axis coordinate and Y-axis coordinate).

Control device 16 corrects a target position (X-axis coordinate and Y-axis coordinate) and the rotation angle of holding member 13d in accordance with the mounting position. Control device 16 lowers holding member 13d at the corrected rotation angle at the corrected target position, and mounts component 91 on board 90. Control device 16 executes the mounting process of mounting multiple components 91 on board 90 by repeating the pick-and-place cycle described above.

### 1-2. Configuration Example of Bulk Feeder 20

Bulk feeder 20 may take various aspects as long as bulk feeder 20 can supply component 91 discharged from component case 50 to component mounter 10. As illustrated in FIG. 2, bulk feeder 20 of the embodiment includes feeder main body 21. Feeder main body 21 is formed in a flat box shape.

Connector 21a and two pins 21b and 21b are provided at a distal end portion (right end portion in the drawing in FIG. 2) of feeder main body 21. When feeder main body 21 is set in slot 12a of component supply device 12, bulk feeder 20 is supplied with power via connector 21a and can communicate with control device 16 of component mounter 10. Two pins 21b and 21b are inserted into guide holes provided in slot 12a, and are used for positioning feeder main body 21 when feeder main body 21 is set in slot 12a.

In addition, bulk feeder 20 includes conveyance unit 30. Conveyance unit 30 is detachably attached to feeder main body 21. In addition, conveyance unit 30 supports set component case 50. Conveyance unit 30 refers to a unitized unit that conveys component 91 discharged from component case 50 from a region where component 91 is received to supply region As0.

After bulk feeder 20 is used for a predetermined mounting process, a removal work of removing internal component 91 in preparation for the next use is performed as one of the maintenance operations. Conveyance unit 30 is provided to be detachable from feeder main body 21 as a unit that functions as a flow path of component 91 in order to improve efficiency on the assumption of the above-described removal work. Conveyance unit 30 of the embodiment includes case support member 31, track unit 32, and coupling member 33.

Case support member 31 is provided to be capable of vibrating with respect to feeder main body 21. Case support member 31 is vibrated by first vibration device 22. Case support member 31 supports set component case 50. Case support member 31 receives component 91 discharged from component case 50. In the embodiment, a portion of case support member 31 that receives component 91 has an inclined surface that is inclined downward in the vertical direction (Z-axis direction) toward the distal end side of bulk feeder 20 with respect to the horizontal plane. Case support member 31 forms a flow path of component 91 extending upward in the vertical direction (Z-axis direction) Track unit 32 is provided to be capable of vibrating with respect to feeder main body 21. Track unit 32 is vibrated by second vibration device 23. Track unit 32 includes conveyance path Rd0 through which multiple components 91 are conveyed, and supply region As0 that communicates with conveyance path Rd0 and opens upward in the vertical direction (Z-axis direction) such that multiple components 91 can be collected. Supply region As0 refers to a region where component mounter 10 can collect component 91. Specifically, supply region As0 is a region in which component 91 can be collected by holding member 13d supported by mounting head 13c, and is included in a movable range of mounting head 13c. In addition, conveyance path Rd0 refers to a flow path of components 91, in which component 91 that flows from case support member 31 to track unit 32 is conveyed toward supply region As0.

Track unit 32 is formed so as to extend along an extending direction of feeder main body 21 (left-right direction in the drawing in FIG. 2) as an overall shape. In track unit 32 of the embodiment, cavity unit 42 is exchangeably attached to track main body 41. For example, cavity unit 42 is at least one plate-shaped member. In track unit 32, one cavity unit 42 selected from multiple types of cavity units 42 corresponding to the shapes of multiple types of components 91 is attached to common track main body 41 to form a unitized track member.

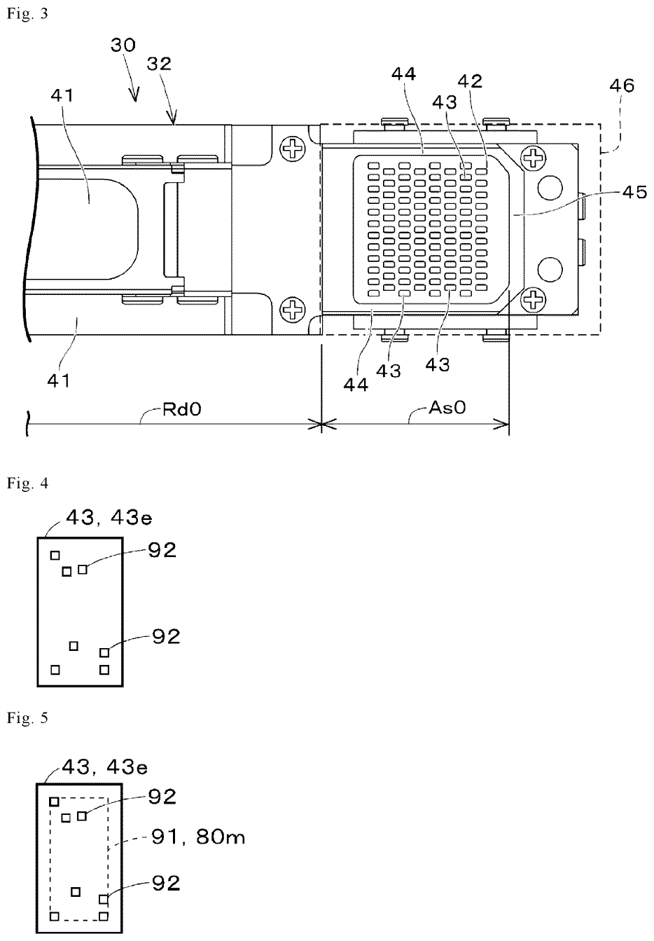

Cavity unit 42 includes multiple cavities 43 in supply region As0, each of which is to accommodate one of components 91 conveyed from conveyance path Rd0 to supply region As0 in track unit 32. Specifically, as illustrated in FIG. 3, cavity unit 42 of the embodiment includes multiple cavities 43 arranged in a predetermined pattern (for example, in a staggered manner). Each of multiple cavities 43 is formed in a rectangular shape slightly larger than the outer shape of component 91 supplied by bulk feeder 20.

Each of multiple cavities 43 is formed to be able to accommodate one component 91 in a posture (normal posture) in which the thickness direction of component 91 matches the vertical direction (Z-axis direction). Pair of side walls 44 and 44 protruding upward in the vertical direction (Z-axis direction) are formed on both edges of track unit 32 in a width direction (up-down direction in the drawing in FIG. 3). Pair of side walls 44 and 44 surround the periphery of conveyance path Rd0 together with distal end portion 45 of track unit 32, and prevent the leakage of components 91 conveyed on conveyance path Rd0.

Shutter 46 capable of closing the opening of supply region As0 is provided above track unit 32 in the vertical direction (Z-axis direction). When track unit 32 is attached to feeder main body 21, shutter 46 is opened and closed under control of a shutter drive device. By opening and closing shutter 46, bulk feeder 20 can prevent protrusion of component 91, mixing of foreign objects into supply region As0, and the like.

Coupling member 33 couples case support member 31 and track unit 32 such that multiple components 91 can flow therebetween. Coupling member 33 is formed in a tubular shape so that multiple components 91 can flow inside. Coupling member 33 has flexibility and absorbs vibrations by being deformed in accordance with the vibration 33 can reduce or block vibration transmitted between case support member 31 and track unit 32 that vibrate independently from each other.

When conveyance unit 30 is attached to feeder main body 21, positive pressure air is supplied by air supply device 24, and conveyance unit 30 causes multiple components 91 to flow from case support member 31 to track unit 32 via coupling member 33. Air supply device 24 of the embodiment can supply positive pressure air, supplied from the outside, from below case support member 31 based on a command from feeder control device 25, and can block the supply of the positive pressure air.

Bulk feeder 20 includes first vibration device 22 and second vibration device 23 provided in feeder main body 21. First vibration device 22 vibrates case support member 31 so as to discharge component 91 from set component case 50. Second vibration device 23 vibrates track unit 32 so that multiple components 91 are conveyed along conveyance path Rd0. When second vibration device 23 vibrates track unit 32, track unit 32 makes an elliptical motion in a side view.

As a result, an external force on the distal end side of bulk feeder 20 (right side in the drawing in FIG. 2) and upward in the vertical direction (Z-axis direction), or an external force on the proximal end side of bulk feeder 20 (left side in the drawing in FIG. 2) and upward in the vertical direction (Z-axis direction) is applied to multiple components 91 on conveyance path Rd0 according to a rotation direction of the elliptical motion of track unit 32. As a result, multiple components 91 are conveyed to the distal end side or the proximal end side of bulk feeder 20 in track unit 32. Bulk feeder 20 can change the conveyance speed, the degree of dispersion, the conveyance direction, and the like of component 91 to be conveyed by controlling the frequency and the amplitude of the vibration applied to track unit 32, the rotation direction of the elliptical motion due to the vibration, and the like.

Bulk feeder 20 includes feeder control device 25. Feeder control device 25 includes a well-known computing device and a storage device, and is configured with a control circuit. In a state where feeder main body 21 is set in slot 12a of component supply device 12, feeder control device 25 is supplied with power via connector 21a, and can communicate with control device 16 of component mounter 10.

Various data, such as a program used for controlling a component supply or a conveyance parameter for component 91, is stored in feeder control device 25. The conveyance parameter is a parameter for driving and controlling second vibration device 23 so that the vibration for vibrating track unit 32 becomes appropriate when component 91 is conveyed in the component supply, and is set in advance in association with each type of component 91, for example.

Feeder control device 25 drives and controls first vibration device 22, second vibration device 23, air supply device 24, the shutter drive device, and the like. For example, feeder control device 25 drives and controls second vibration device 23 based on a parameter set in advance to execute a component supply process. As a result, track unit 32 is vibrated, and component 91 on conveyance path Rd0 is conveyed by receiving an

Component case 50 accommodates multiple components 91 in a bulk state. Component case 50 is an external device that is exchangeably set on case support member 31 in conveyance unit 30 of bulk feeder 20. Component case 50 is formed in a flat box shape, similar to feeder main body 21.

For example, feeder control device 25 discharges component 91 from component case 50 based on a supply command from the outside. Specifically, feeder control device 25 drives and causes first vibration device 22 so as to vibrate case support member 31 to which component case 50 is attached. When component case 50 vibrates, component 91 is discharged from a discharge port. Discharged component 91 drops to an inclined portion of case support member 31 located below the discharge port and moves along the inclined surface of the inclined portion. As a result, component 91 is retained at a lower end portion of the inclined portion.

In this state, feeder control device 25 commands air supply device 24 to supply the positive pressure air. The positive pressure air supplied from air supply device 24 blows up retained multiple components 91, and flows through the flow path formed in case support member 31 together with component 91. As a result, the positive pressure air and multiple components 91 flow from case support member 31 to track unit 32 via coupling member 33, and reach conveyance path Rd0 of track unit 32. The positive pressure air is exhausted to the outside from an exhaust port formed in the cover of track unit 32.

When track unit 32 is vibrated by second vibration device 23 after component 91 reaches conveyance path Rd0, multiple components 91 are conveyed toward supply region As0. In addition, vibration for moving component 91 to supply region As0 side or vibration for moving component 91 to component case 50 side is applied to track unit 32 according to the supply amount of component 91 in supply region As0 or the like. A part of multiple components 91 conveyed to supply region As0 are accommodated in cavities 43. Component 91 that is not accommodated in cavity 43 is moved in conveyance path Rd0 by vibration by second vibration device 23, and is removed from supply region As0. With such a component supply process, component 91 accommodated in cavity 43 is brought into a state of being able to be collected by component mounter 10.

### 1-3. Configuration Example of Collection Support Device 60

For example, foreign object 92 may adhere to cavity 43 in which component 91 is accommodated. FIG. 4 illustrates an example of cavity 43 to which foreign object 92 adheres. The figure is a schematic diagram of one cavity 43 in which component 91 is not accommodated when viewed from above in the vertical direction (Z-axis direction). For example, foreign object 92, such as that formed by peeling off an electrode part of component 91, has the same luminance as that of an electrode portion of component 91.

Therefore, component mounter 10 may erroneously detect component 91 from foreign object 92. FIG. 5 illustrates a recognition example in a case where foreign object 92 in FIG. 4 is erroneously detected as component 91.

For example, control device 16 of component mounter 10 performs image processing (for example, binarization processing) on the captured image of cavity region (in this case, a rectangular region indicated by a broken line) including the recognized portion (seven foreign objects 92 in FIG. 5) through the binarization processing. For example, control device 16 determines that component 91 is accommodated in cavity 43 in a case where the area of the rectangular region is included in an assumed range of the area of component 91, and determines that component 91 is not accommodated in cavity 43 in a case where the area of the rectangular region is not included in the assumed range of the area of component 91.

In the example illustrated in FIG. 5, the area of the rectangular region is included in the assumed range of the area of component 91. Therefore, control device 16 of component mounter 10 may erroneously determine that component 91 is accommodated in cavity 43 even though component 91 is not accommodated in cavity 43, and may fail to collect component 91. The above description can be similarly applied to a case where the difference between reference image PC0 obtained by capturing empty cavity 43e to which foreign object 92 does not adhere and component 91 is not accommodated and inspection image PD0 of cavity 43 to which foreign object 92 adheres is calculated to determine whether component 91 is accommodated in cavity 43.

Therefore, collection support device 60 is applied to the component collection of bulk feeder 20. Collection support device 60 can determine the presence or absence of component 91 in cavity 43, even in a case where the state of cavity 43 changes with the production of the product board. Specifically, collection support device 60 includes track unit 32, cavity unit 42, imaging section 61, update section 62, and determination section 63. As described above, track unit 32 includes conveyance path Rd0 that conveys component 91 discharged from component case 50 accommodating component 91 in a bulk state to supply region As0 from which component mounter 10 can collect component 91. Cavity unit 42 includes multiple cavities 43 in supply region As0, each of which is to accommodate one of components 91 conveyed from conveyance path Rd0 to supply region As0 in track unit 32.

Imaging section 61, update section 62, and determination section 63 can be provided in various computing devices, control devices, management devices, and the like. For example, at least a part of imaging section 61, update section 62, and determination section 63 can be provided in control device 16 of component mounter 10.

At least a part of imaging section 61, update section 62, and determination section 63 can be provided in a management device that manages component mounter 10. At least a part of imaging section 61, update section 62, and determination section 63 can be formed on a cloud.

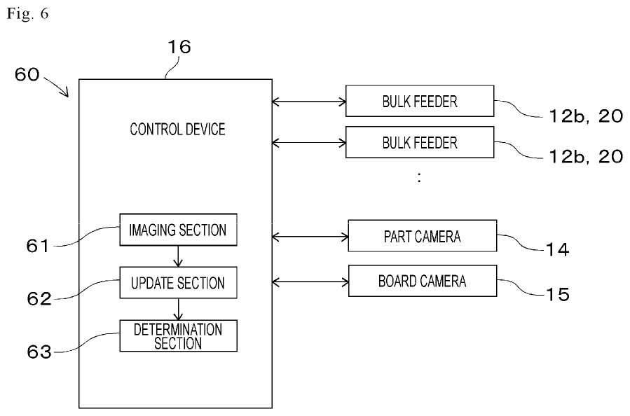

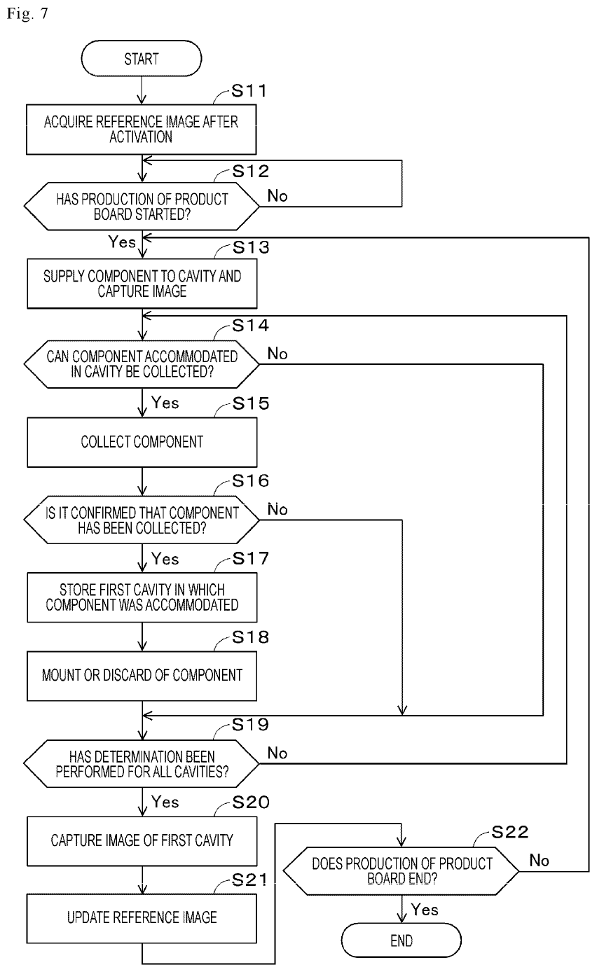

As illustrated in FIG. 6, imaging section 61, update section 62, and determination section 63 of the embodiment are provided in control device 16 of component mounter 10. In addition, collection support device 60 of the embodiment executes control according to a flowchart illustrated in FIG. 7. Specifically, imaging section 61 performs processing illustrated in step S20. Update section 62 performs processing illustrated in Step S21. After the processing illustrated in step S21 is executed, determination section 63 performs the determination illustrated in step S14. Control device described in the present description can be appropriately selected and applied. In addition, the matters described in the present description can be appropriately combined.

It is possible to ensure that component 91 is not accommodated in cavity 43 in which it is confirmed that component 91 has been collected by component mounter 10 at least at the time of confirmation. In the present description, among multiple cavities 43, at least one cavity 43 in which it is confirmed that component 91 has been collected by component mounter 10 is referred to as first cavity 43a. For each of first cavities 43a, imaging section 61 captures an image of first cavity 43a during a capturing available period in which it is expected that component 91 is not accommodated in first cavity 43a.

For each of first cavities 43a, update section 62 updates reference image PC0 obtained by capturing empty cavity 43e in which component 91 is not accommodated using first image PC1 obtained by capturing first cavity 43a by imaging section 61. As a result, for example, in a case where the state of cavity 43 changes with the production of the product board, such as when foreign object 92 adheres to cavity 43, update section 62 can update reference image PC0 using first image PC1 after the state of cavity 43 changes. Determination section 63 can determine whether component 91 is accommodated in first cavity 43a using reference image PC0 updated by update section 62. Hereinafter, an example of determination of the presence or absence of component 91 by collection support device 60 will be described.

For example, component 91 is not accommodated in cavity 43 after component mounter 10 is activated (after the power is turned on). Therefore, control device 16 acquires reference image PC0 after component mounter 10 is activated (step S11 illustrated in FIG. 7). For example, control device 16 can capture an image of cavity unit 42 using board camera 15. Control device 16 can acquire reference image PC0 for each of multiple cavity units 42 of cavity unit 42.

Next, control device 16 determines whether the production of the product board has started (step S12). When the production of the product board has started (Yes in step S12), control device 16 supplies component 91 to cavity 43 (step S13). As described above, control device 16 causes feeder control device 25 to execute the component supply process. Feeder control device 25 can drive and control first vibration device 22, second vibration device 23, air supply device 24, and the like, so that component 91 can be accommodated in cavity 43.

When component 91 is accommodated in cavity 43, for example, control device 16 captures an image of cavity unit 42 using board camera 15 (step S13). Control device 16 acquires inspection image PD0 for each of multiple cavity units 42 of cavity unit 42. Inspection image PD0 refers to an image obtained by capturing cavity 43 after the accommodation of component 91 in cavity 43 is attempted for supplying component 91. When the production of the product board is not started (No in step S12), the control by collection support device 60 returns to the determination illustrated in step S12, and control device 16 waits until the production of the product board starts.

Next, control device 16 determines whether component 91 accommodated in cavity 43 can be collected (step S14). For example, similar to accommodated in cavity 43, using inspection image PD0 and reference image PC0. Details of the determination of the presence or absence of component 91 by determination section 63 will be described later.

When component 91 is accommodated in cavity 43 and component 91 can be collected (Yes in step S14), control device 16 collects component 91 using holding member 13d supported by mounting head 13c (step S15). In a case where one component 91 is accommodated in cavity 43 in a posture in which the thickness direction of component 91 matches the vertical direction (Z-axis direction) (normal posture), control device 16 can determine that component 91 can be collected.

Next, control device 16 determines whether component 91 has been collected by holding member 13d (step S16). For example, control device 16 can capture an image of component 91 held by holding member 13d using part camera 14. Control device 16 can determine whether component 91 has been collected by holding member 13d by performing image processing on the captured image. Specifically, control device 16 determines that component 91 has been collected by holding member 13d in a case where component 91 can be recognized as a result of the image processing, and determines that component 91 has not been collected by holding member 13d in a case where component 91 cannot be recognized.

When it is confirmed that component 91 has been collected (Yes in step S16), cavity 43 in which component 91 is accommodated is first cavity 43a. Therefore, control device 16 stores first cavity 43a in which component 91 was accommodated (step S17). Specifically, control device 16 stores position information of first cavity 43a in cavity unit 42. For example, the position information can be represented by position coordinates or a matrix. Control device 16 mounts or discards component 91 according to the collection state of component 91 (step S18).

Specifically, in a case where the position and the angle of component 91 with respect to holding member 13d are included in an allowable range in which component 91 can be mounted, control device 16 mounts component 91 at a predetermined position of board 90. In addition, in a case where the position and the angle of component 91 with respect to holding member 13d are not included in the allowable range in which component 91 can be mounted, control device 16 discards component 91. In this case, control device 16 puts component 91 into a disposal box. When component 91 is mounted or discarded, when component 91 cannot be collected (No in step S14), or when it is not confirmed that component 91 has been collected (No in step S16), the control by collection support device 60 proceeds to the determination illustrated in step S19.

Specifically, control device 16 determines whether it is determined, for all cavities 43 of cavity unit 42, whether component 91 accommodated in cavity 43 can be collected (step S19). When determination has been performed for all cavities 43 (Yes in step S19), imaging section 61 captures an image of first cavity 43a during a predetermined capturing available period (step S20). Update section 62 updates reference image PC0 (step S21). When determination has not been performed for all cavities 43 (No in step S19), the control by collection support device 60 returns to the determination illustrated in step S14, and the above-described processing and determination are repeated until it is determined for all cavities 43.

For each of first cavities 43a, imaging section 61 captures an image of first cavity 43a during a capturing available period in which it is expected that component 91 is not accommodated in first cavity 43a (step S20). For example, imaging section 61 can capture an image of cavity unit 42 using board camera 15. Imaging section 61 can identify the position of first cavity 43a based on the stored position information of first cavity 43a and acquire first image PC1 in which first cavity 43a is captured.

The capturing available period may be any period during which it is expected that component 91 is not accommodated in first cavity 43a, and is not particularly limited. For example, it is possible to ensure that component 91 is not accommodated in first cavity 43a during a period from when it is confirmed that component 91 has been collected from first cavity 43a until the accommodation of component 91 in first cavity 43a is attempted for supplying next component 91.

Therefore, the capturing available period may be defined as a period from when it is confirmed that component 91 has been collected from first cavity 43a until the accommodation of component 91 in first cavity 43a is attempted for supplying next component 91. As described above, the processing illustrated in step S20 of capturing an image of first cavity 43a is executed after it is confirmed that component 91 has been collected from first cavity 43a (Yes in step S16). In addition, when reference image PC0 is updated by update section 62, control device 16 determines whether to end the production of the product board (step S22).

When the production of the product board is ended (Yes in step S22), the control by collection support device 60 temporarily ends. When the production of the product board is continued (No in step S22), the control by collection support device 60 returns to the processing illustrated in step S13, and control device 16 supplies component 91 to cavity 43 (step S13). As described above, imaging section 61 of the embodiment can capture an image of first cavity 43a during the capturing available period, and can reliably capture an image of cavity 43 (first cavity 43a) in which component 91 is not accommodated.

As illustrated in the flowchart in FIG. 7, imaging section 61 can capture an image of first cavity 43a each time the capturing available period occurs. In this case, imaging section 61 can acquire first image PC1 in which first cavity 43a is captured each time the accommodation of component 91 is attempted for supplying component 91. In addition, imaging section 61 can also capture an image of first cavity 43a each time the number of times the capturing available period occurs reaches a predetermined number of times. In this case, imaging section 61 can acquire first image PC1 in which first cavity 43a is captured each time the accommodation of component 91 is attempted a predetermined number of times. In addition, in this case, imaging section 61 can reduce the work time related to capturing as compared with a case where an image of first cavity 43a is captured each time the capturing available period occurs.

Immediately after component mounter 10 is activated or immediately high possibility that the state of cavity 43 is changed. Therefore, imaging section 61 can capture an image of at least first cavity 43a in a case where the capturing available period first occurs after component mounter 10 is activated. In addition, imaging section 61 can also capture an image of at least first cavity 43a in a case where the capturing available period first occurs after the maintenance of cavity unit 42 ends. In either case, imaging section 61 can capture an image of first cavity 43a in a situation where there is a high possibility that the state of cavity 43 is changed.

For each of first cavities 43a, update section 62 updates reference image PC0 obtained by capturing empty cavity 43e in which component 91 is not accommodated using first image PC1 obtained by capturing first cavity 43a by imaging section 61 (step S21). Specifically, update section 62 sets first image PC1 acquired by imaging section 61 as reference image PC0 instead of reference image PC0 acquired after component mounter 10 is activated. When first image PC1 is newly acquired by imaging section 61, update section 62 sets first image PC1 currently acquired by imaging section 61 as reference image PC0 instead of first image PC1 acquired by imaging section 61 in a previous time.

Update section 62 may set latest first image PC1 acquired by imaging section 61 as reference image PC0 by repeating the above processing each time first image PC1 is acquired by imaging section 61. Therefore, for example, even in a case where the state of cavity 43 changes with the production of the product board, such as when foreign object 92 adheres to cavity 43, update section 62 may set first image PC1 after the state of cavity 43 changes as reference image PC0.

Determination section 63 determines whether component 91 is accommodated in first cavity 43a using reference image PC0 updated by update section 62 (step S14 after the processing illustrated in step S21 is executed). For example, determination section 63 calculates a difference between an image feature value of inspection image PD0 obtained by capturing first cavity 43a after the accommodation of component 91 in first cavity 43a is attempted for supplying component 91 and an image feature value of reference image PC0 for each pixel.

Determination section 63 can determine that component 91 is accommodated in first cavity 43a in a case where there is specific region AR0 in which the difference between the image feature values exceeds a predetermined range, and the area of a closed region including specific region AR0 is included in the assumed range of the area of component 91. In a case where specific region AR0 is not present or the area of the closed region including specific region AR0 is not included in the assumed range of the area of component 91, determination section 63 can determine that component 91 is not accommodated in first cavity 43a. Determination section 63 can calculate the difference using a well-known image feature value. For example, determination section 63 can calculate the difference using the luminance, brightness, saturation, and the like of the pixel. Determination section 63 of the embodiment calculates the difference using the luminance of the pixel.

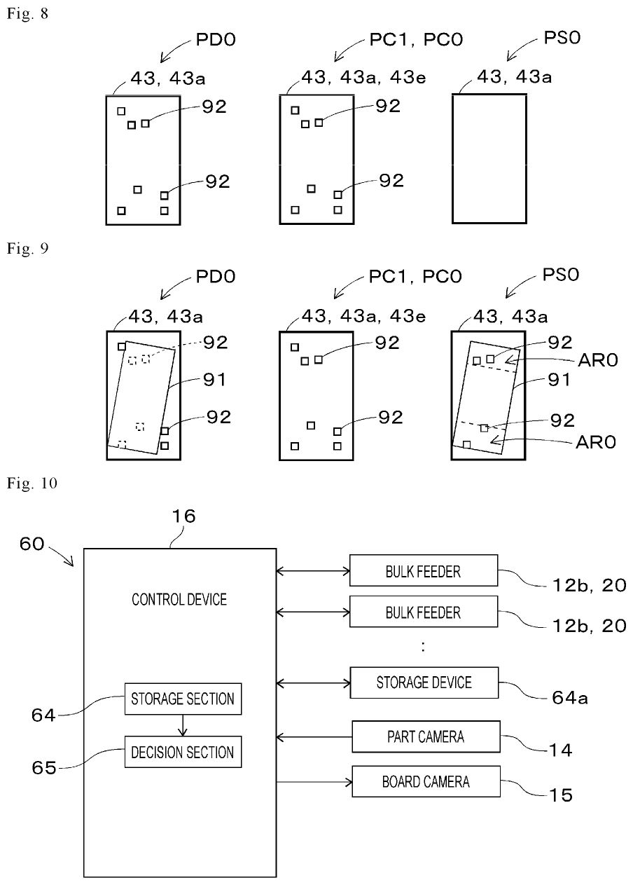

FIG. 8 illustrates a calculation example of difference image PS0. Inspection image PD0 in FIG. 8 illustrates an image obtained by capturing first cavity 43a accommodated. Reference image PC0 in FIG. 8 illustrates an image obtained by capturing empty cavity 43e to which foreign object 92 illustrated in FIG. 4 adheres. Difference image PSO in FIG. 8 illustrates an image obtained by calculating a difference between the image feature value of inspection image PD0 and the image feature value of reference image PC0 for each pixel.

Since the image feature value (luminance) of the region of foreign object 92 in inspection image PD0 is equal to the image feature value (luminance) of the region of foreign object 92 in reference image PC0, the region of foreign object 92 disappears in difference image PSO in which the difference between the image feature values (luminances) is calculated for each pixel. Therefore, difference image PSO illustrated in FIG. 8 in which nothing is captured is obtained. In this case, there is no specific region AR0 in which the difference between the image feature values exceeds the predetermined range. Therefore, determination section 63 can determine that component 91 is not accommodated in first cavity 43a.

FIG. 9 illustrates another calculation example of difference image PS0. Inspection image PD0 in FIG. 9 illustrates an image obtained by capturing first cavity 43a in which foreign object 92 illustrated in FIG. 4 adheres and component 91 is accommodated. In inspection image PD0 in FIG. 9, four foreign objects 92 among seven foreign objects 92 illustrated in FIG. 4 are hidden by component 91, and three foreign objects 92 are captured. Reference image PC0 in FIG. 9 illustrates an image obtained by capturing empty cavity 43e to which foreign object 92 illustrated in FIG. 4 adheres. Difference image PSO in FIG. 9 illustrates an image obtained by calculating a difference between the image feature value of inspection image PD0 and the image feature value of reference image PC0 for each pixel.

Similar to the case illustrated in FIG. 8, in difference image PS0 illustrated in FIG. 9, the regions of three foreign objects 92 that are not hidden by component 91 disappear. In addition, a difference between the image feature value (luminance) of the region of the electrode portion of component 91 in inspection image PD0 in FIG. 9 and the image feature value (luminance) of the corresponding region in reference image PC0 exceeds a predetermined range, and specific region AR0 is present. In addition, the area of the closed region (in this case, the rectangular region) including specific region AR0 is included in the assumed range of the area of component 91. Therefore, determination section 63 can determine that component 91 is accommodated in first cavity 43a. Since the electrode portion and foreign object 92 have the same luminance, the region of foreign object 92 is missing in specific region AR0.

### 1-4. Another Configuration Example of Collection Support Device 60

For example, even in the case of cavity 43 that cannot be collected due to the adhesion of foreign object 92, component 91 may be collected from cavity 43 that cannot be collected depending on the positional relationship between component 91 and foreign object 92, such as a case where foreign object 92 is covered by component 91.

Therefore, collection support device 60 of the second embodiment includes track unit 32, cavity unit 42, storage section 64, and decision section 65. As discharged from component case 50 accommodating component 91 in a bulk state to supply region As0 from which component mounter 10 can collect component 91. Cavity unit 42 includes multiple cavities 43 in supply region As0, each of which is to accommodate one of components 91 conveyed from conveyance path Rd0 to supply region As0 in track unit 32.

Storage section 64 and decision section 65 can be provided in various computing devices, control devices, management devices, and the like. For example, at least a part of storage section 64 and decision section 65 can be provided in control device 16 of component mounter 10. At least a part of storage section 64 and decision section 65 may be provided in a management device that manages component mounter 10. At least a part of storage section 64 and decision section 65 may be formed on a cloud. As illustrated in FIG. 10, also in collection support device 60 of the second embodiment, storage section 64 and decision section 65 are provided in control device 16 of component mounter 10.

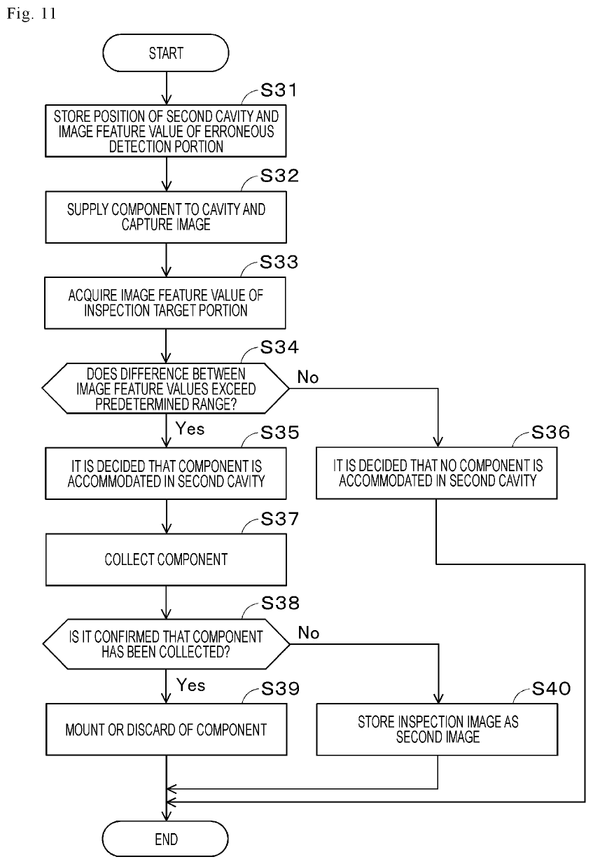

In addition, collection support device 60 of the second embodiment executes control according to a flowchart illustrated in FIG. 11. Specifically, storage section 64 performs processing illustrated in step S31 and step S40. Decision section 65 performs processing and decision illustrated in steps S33 to S36. Control device 16 of component mounter 10 performs other processing and determinations. In the present description, description overlapping with the matters of collection support device 60 of the first embodiment including track unit 32, cavity unit 42, imaging section 61, update section 62, and determination section 63 is omitted. In addition, the matters described in collection support device 60 of the first embodiment and collection support device 60 of the second embodiment can be appropriately selected and applied, and can be appropriately combined.

Cavity 43 which is at least one of multiple cavities 43 of cavity unit 42 and in which it is confirmed that component 91 cannot be collected by component mounter 10 is referred to as second cavity 43b. As described above, for example, control device 16 can image component 91 held by holding member 13d using part camera 14. Control device 16 can determine whether component 91 has been collected by holding member 13d by performing image processing on the captured image.

Storage section 64 stores, for each of second cavities 43b, the position of second cavity 43b in cavity unit 42 and the image feature value enabling identification of erroneous detection portion 80m erroneously detected as component 91 in second image PC2 obtained by capturing second cavity 43b in storage device 64a in association with each other (step S31 illustrated in FIG. 11). For example, the position of second cavity 43b can be represented by position coordinates or a matrix. In addition, for example, control device 16 can acquire second image PC2 by capturing second cavity 43b using board camera 15.

In the example illustrated in FIG. 5, a rectangular region indicated by a broken line including seven foreign objects 92 is erroneously detected as component 91. Therefore, in this case, erroneous detection portion 80m corresponds to the rectangular region. Erroneous detection portion 80m can be identified using various image feature values. The image feature value will be described later. In addition, storage device 64a may take various aspects as long as storage device 64a can store the information described above. For example, a well-known storage device, database, or the like can be used as storage device 64a. Storage device 64a can also be formed on a cloud.

Next, control device 16 supplies component 91 to cavity 43 (step S32). As described above, control device 16 causes feeder control device 25 to execute the component supply process. Feeder control device 25 can drive and control first vibration device 22, second vibration device 23, air supply device 24, and the like, so that component 91 can be accommodated in cavity 43. When component 91 is accommodated in cavity 43, for example, control device 16 captures an image of cavity unit 42 using board camera 15 (step S32). Decision section 65 can identify the position of second cavity 43b based on the position of second cavity 43b stored in storage device 64a, and acquire inspection image PD0 in which second cavity 43b is captured.

In this manner, for each of second cavities 43b, decision section 65 can acquire inspection image PD0 obtained by capturing second cavity 43b after the accommodation of component 91 in second cavity 43b is attempted for supplying component 91. Decision section 65 decides whether component 91 is accommodated in second cavity 43b, based on a degree of matching between the image feature value enabling identification of inspection target portion 80c detected as component 91 in inspection image PD0 and the image feature value enabling identification of erroneous detection portion 80m stored in storage device 64a.

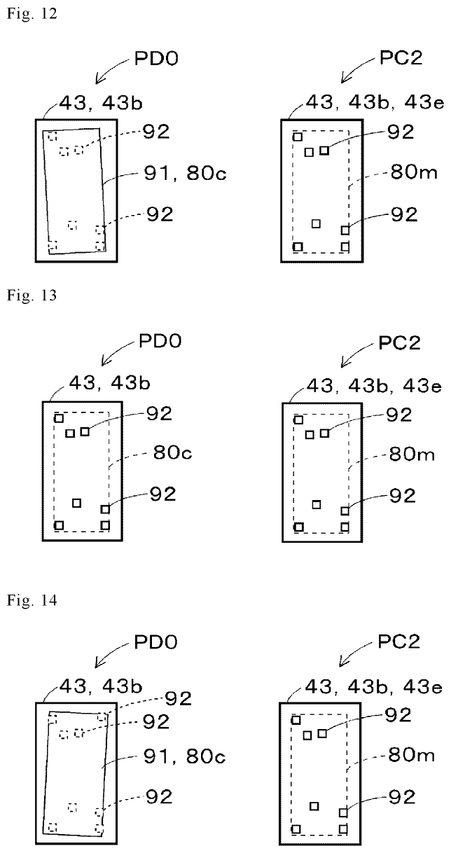

FIG. 12 illustrates an example of inspection image PD0 and second image PC2 in a case where component 91 is accommodated in second cavity 43b. In this case, component 91 is detected, and inspection target portion 80c indicates the shape of component 91. FIG. 13 illustrates an example of inspection image PD0 and second image PC2 in a case where component 91 is not accommodated in second cavity 43b. In this case, seven foreign objects 92 are erroneously detected as component 91, and inspection target portion 80c indicates a rectangular region including seven foreign objects 92. In either case, seven foreign objects 92 are covered by component 91.

The image feature value is not limited as long as inspection target portion 80c and erroneous detection portion 80m can be identified. For example, the positions of inspection target portion 80c and erroneous detection portion 80m in second cavity 43b can be used as the image feature value. For example, the reference position can be set at the center of second cavity 43b. In addition, inspection target portion 80c is a rectangular region, and the center of the rectangular region may be defined as the position of inspection target portion 80c (step S33). Similarly, erroneous detection portion 80m is a rectangular region, and the center of the rectangular region may be defined as the position of erroneous detection portion 80m.

In a case where component 91 is accommodated in second cavity 43b, the position of component 91 in second cavity 43b is more likely to vary as compared with foreign object 92 adhering to second cavity 43b. Therefore, decision section 65 calculates a difference between the image feature value (position) of inspection target portion 80c in inspection image PD0 and the image feature value (position) of erroneous detection feature values (positions) exceeds the predetermined range (Yes in step S34), decision section 65 decides that component 91 is accommodated in second cavity 43b (step S35).

In addition, when the difference between the image feature values (positions) is within the predetermined range (No in step S34), decision section 65 decides that component 91 is not accommodated in second cavity 43b (step S36). For example, the predetermined range can be derived in advance by simulation, verification using an actual device, or the like. In the example illustrated in FIG. 12, the difference between the image feature values (positions) exceeds the predetermined range, and decision section 65 can decide that component 91 is accommodated in second cavity 43b. In addition, in the example illustrated in FIG. 13, the difference between the image feature values (positions) is within the predetermined range, and decision section 65 can decide that component 91 is not accommodated in second cavity 43b.

The inclination of inspection target portion 80c and erroneous detection portion 80m with respect to second cavity 43b can also be used as the image feature value. For example, the reference angle may be set in the longitudinal direction of second cavity 43b. In addition, inspection target portion 80c is a rectangular region, and an angle formed by the longitudinal direction of the rectangular region with respect to the reference angle may be defined as an inclination of inspection target portion 80c (step S33). Similarly, erroneous detection portion 80m is a rectangular region, and an angle formed by the longitudinal direction of the rectangular region with respect to the reference angle may be defined as an inclination of erroneous detection portion 80m.

In addition, the luminance of inspection target portion 80c in a case where inspection target portion 80c is component 91 may be different from the luminance of inspection target portion 80c in a case where inspection target portion 80c is foreign object 92. In this case, the luminance of inspection target portion 80c and erroneous detection portion 80m can be used as the image feature value. The above description for the luminance can be similarly applied to the area. In addition, the above description for the luminance can be similarly applied to a ratio of a long side to a short side in a case where inspection target portion 80c and erroneous detection portion 80m are rectangular in shape.

At least one of the image feature values described above can be used. That is, as the image feature value, at least one of the positions of inspection target portion 80c and erroneous detection portion 80m in second cavity 43b, the inclinations of inspection target portion 80c and erroneous detection portion 80m with respect to second cavity 43b, the luminance of inspection target portion 80c and erroneous detection portion 80m, the areas of inspection target portion 80c and erroneous detection portion 80m, and the ratio of the long side to the short side in a case where inspection target portion 80c and erroneous detection portion 80m are rectangular in shape can be used.

As illustrated in FIG. 14, there is a possibility that the image feature value of erroneous detection portion 80m in second image PC2 varies due to foreign object 92 newly adhering to second cavity 43b. In a case where decision section 65 makes an erroneous decision due to the variation and component 91 cannot be collected by device 64a. Therefore, in a case where decision section 65 decides that component 91 is accommodated in second cavity 43b, but component 91 cannot be collected by component mounter 10, storage section 64 stores inspection image PD0 in storage device 64a as second image PC2.

Specifically, when determining section 65 decides that component 91 is accommodated in second cavity 43b and component 91 can be collected, control device 16 collects component 91 using holding member 13d supported by mounting head 13c (step S37). Control device 16 determines whether component 91 has been collected by holding member 13d (step S38). For example, control device 16 can capture an image of component 91 held by holding member 13d using part camera 14. Control device 16 can determine whether component 91 has been collected by holding member 13d by performing image processing on the captured image.

When it is confirmed that component 91 has been collected (Yes in step S38), control device 16 mounts or discards component 91 according to the collection state of component 91 as described above (step S39). The control by collection support device 60 temporarily ends. When it is not confirmed that component 91 has been collected (No in step S38), storage section 64 stores inspection image PD0 illustrated in FIG. 14 in storage device 64a as second image PC2 (step S40).

In inspection image PD0 illustrated in FIG. 12, the inclination direction of inspection target portion 80c with respect to second cavity 43b is the left direction in the drawing. In inspection image PD0 illustrated in FIG. 14, the inclination direction of inspection target portion 80c with respect to second cavity 43b is the right direction in the drawing. As described above, inspection image PD0 illustrated in FIG. 14 is different from inspection image PD0 illustrated in FIG. 12 in the inclination direction of inspection target portion 80c with respect to second cavity 43b. When second image PC2 stored in storage device 64a is updated, the control by collection support device 60 temporarily ends.

### 2. Collection Support Method

The above description for collection support device 60 of the first embodiment can be similarly applied to a collection support method of the first embodiment. Specifically, the collection support method of the first embodiment is applied to the component collection of bulk feeder 20 including track unit 32 and cavity unit 42, and includes an image-capturing step, an updating step, and a determination step. The image capturing step corresponds to the control performed by imaging section 61. The updating step corresponds to the control performed by update section 62. The determination step corresponds to the control performed by determination section 63.

In addition, the above description for collection support device 60 of the second embodiment can be similarly applied to a collection support method of the second embodiment. Specifically, the collection support method of the second embodiment is applied to the component collection of bulk feeder 20 including track unit 32 and cavity unit 42, and includes a storage step and a decision step. The storage step corresponds to the control performed by storage section 64. The decision step corresponds to the control performed by decision section 65.

### 3. Example of Effects of Embodiment

According to collection support device 60, it is possible to determine the presence or absence of component 91 in cavity 43 even in a case where the state of cavity 43 changes with the production of the product board. The above description for collection support device 60 can be similarly applied to the collection support method.

### REFERENCE SIGNS LIST

10: Component mounter, 20: Bulk feeder, 32: Track unit,
42: Cavity unit, 43: Cavity, 43a: First cavity,
43b: Second cavity, 43e: Empty cavity, 50: Component case,
60: Collection support device, 61: Imaging section, 62: Update section, 63: Determination section,
64: Storage section, 64a: Storage device, 65: Decision section, 80c: Inspection target portion,
80m: Erroneous detection portion, 91: Component, As0: Supply region, Rd0: Conveyance path,
AR0: Specific region, PC0: Reference image, PC1: First image,
PC2: Second image, PD : Inspection image

1. A collection support device comprising:
a track unit that includes a conveyance path configured to convey a component discharged from a component case accommodating the component in a bulk state to a supply region in which the component is collectable by a component mounter;
a cavity unit that includes multiple cavities in the supply region, each of the cavities being configured to accommodate one of the components conveyed from the conveyance path to the supply region in the track unit;
an imaging section configured to capture a first cavity during a capturing available period in which it is expected that the component is not accommodated in the first cavity, for each of the first cavities which are at least one of the multiple cavities and for which it is confirmed that the component has been collected by the component mounter;
an update section configured to update a reference image obtained by capturing an empty cavity in which the component is not accommodated, using a first image obtained by capturing the first cavity by the imaging section, for each of the first cavities; and
a determination section configured to determine whether the component is accommodated in the first cavity, using the reference image updated by the update section.

2. The collection support device according to claim 1, wherein the capturing available period is a period from when it is confirmed that the component has been collected from the first cavity until accommodation of the component in the first cavity is attempted for supplying a next component.

3. The collection support device according to claim 1, wherein the imaging section captures the first cavity each time the capturing available period occurs or each time a number of times the capturing available period occurs reaches a predetermined number of times.

4. The collection support device according to claim 1, wherein the imaging section captures at least the first cavity in a case where the capturing available period first occurs after the component mounter is activated or after maintenance of the cavity unit ends.

5. The collection support device according to claim 1, wherein the determination section calculates a difference between an image feature value of an inspection image obtained by capturing the first cavity after accommodation of the component in the first cavity is attempted for supplying the component and the image feature value of the reference image for each pixel, to determine that the component is accommodated in the first cavity in a case where there is a specific region in which the difference between the image feature values exceeds a predetermined range and an area of a closed region including the specific region is included in an assumed range of an area of the component, and to determine that the component is not accommodated in the first cavity in a case where there is no specific region or the area of the closed region including the specific region is not included in the assumed range of the area of the component.

6. A collection support device comprising:
a track unit that includes a conveyance path configured to convey a component discharged from a component case accommodating the component in a bulk state to a supply region in which the component is collectable by a component mounter;
a cavity unit that includes multiple cavities in the supply region, each of the cavities being configured to accommodate one of the components conveyed from the conveyance path to the supply region in the track unit;
a storage section configured to store a position of a second cavity in the cavity unit and an image feature value enabling identification of an erroneous detection portion that is erroneously detected as the component in a second image obtained by capturing the second cavity in association with each other in a storage device, for each of the second cavities which are at least one of the multiple cavities and for which it is confirmed that the component is not collectable by the component mounter; and
a decision section configured to decide whether the component is accommodated in the second cavity, based on a degree of matching between the image feature value enabling identification of an inspection target portion detected as the component in an inspection image obtained by capturing the second cavity after accommodation of the component in the second cavity is attempted for supplying the component and the image feature value enabling identification of the erroneous detection portion stored in the storage device, for each of the second cavities.

7. The collection support device according to claim 6, wherein the decision section calculates a difference between the image feature value of the inspection target portion in the inspection image and the image feature value of the erroneous detection portion in the second image, and decides that the component is accommodated in the second cavity in a case where the difference between the image feature values exceeds a predetermined range, and decides that the component is not accommodated in the second cavity in a case where the difference between the image feature values is within the predetermined range.

8. The collection support device according to claim 6, wherein the storage section stores the inspection image as the second image in the storage device in a case where the decision section decided that the component was accommodated in the second cavity, but the component was not able to be collected by the component mounter.

9. The collection support device according to claim 6, wherein the image feature value is at least one of the following: positions of the inspection target portion and the erroneous detection portion in the second cavity; inclinations of the inspection target portion and the erroneous detection portion with respect to the second cavity; luminances of the inspection target portion and the erroneous detection portion; areas of the inspection target portion and the erroneous detection portion; and a ratio of a long side to a short side in a case where the inspection target portion and the erroneous detection portion are rectangular in shape.

10. A collection support method applied to a component collection of a bulk feeder including a track unit that includes a conveyance path configured to convey a component discharged from a component case accommodating the component in a bulk state to a supply region in which the component is collectable by a component mounter, and a cavity unit that includes multiple cavities in the supply region, each of the cavities being configured to accommodate one of the components conveyed from the conveyance path to the supply region in the track unit, the collection support method comprising:
an image capturing step of capturing a first cavity during a capturing available period in which it is expected that the component is not accommodated in the first cavity, for each of the first cavities which are at least one of the multiple cavities and for which it is confirmed that the component has been collected by the component mounter;
an updating step of updating a reference image obtained by capturing an empty cavity in which the component is not accommodated, using a first image obtained by capturing the first cavity by the image capturing step, for each of the first cavities; and
a determination step of determining whether the component is accommodated in the first cavity, using the reference image updated by the updating step.

11. A collection support method applied to a component collection of a bulk feeder including a track unit that includes a conveyance path configured to convey a component discharged from a component case accommodating the component in a bulk state to a supply region in which the component is collectable by a component mounter, and a cavity unit that includes multiple cavities in the supply region, each of the cavities being configured to accommodate one of the components conveyed from the conveyance path to the supply region in the track unit, the collection support method comprising:
a storage step of storing a position of a second cavity in the cavity unit and an image feature value enabling identification of an erroneous detection portion that is erroneously detected as the component in a second image obtained by capturing the second cavity in association with each other in a storage device, for each of the second cavities which are at least one of the multiple cavities and for which it is confirmed that the component is not collectable by the component mounter; and
a decision step of deciding whether the component is accommodated in the second cavity, based on a degree of matching between the image feature value enabling identification of an inspection target portion detected as the component in an inspection image obtained by capturing the second cavity after accommodation of the component in the second cavity is attempted for supplying the component and the image feature value enabling identification of the erroneous detection portion stored in the storage device, for each of the second cavities.
